(19) United States
(12) Patent Application Publication
(10) Pub. No.: US 2025/0192045 A1
(43) Pub. Date: Jun. 12, 2025

(54) SEMICONDUCTOR INTEGRATED CIRCUIT DEVICE

(71) Applicant: Socionext Inc., Kanagawa (JP)

(72) Inventor: Hidetoshi TANAKA, Yokohama-shi (JP)

(21) Appl. No.: 19/056,287

(22) Filed: Feb. 18, 2025

Related U.S. Application Data
(63) Continuation of application No. PCT/JP2022/032871, filed on Aug. 31, 2022.

(51) Int. Cl. H01L 23/528; H01L 23/522; H10D 84/83; H10D 89/60

(52) U.S. Cl. CPC H01L 23/5283; H01L 23/5228; H10D 84/83138; H10D 89/611

(57) ABSTRACT

In an output circuit included in an IO cell, between transistor rows of an output transistor, placed is a first interconnect connected to the gates of the transistors. Second interconnects connected to the drains of the transistors are placed for the transistor rows. The first interconnect is located between the second interconnects separated from each other in planar view. That is, the second interconnects connected to the drains of the transistors do not overlap the first interconnect connected to the gates of the transistors in planar view.

### CROSS-REFERENCE TO RELATED APPLICATIONS

This is a continuation of International Application No. PCT/JP2022/032871 filed on Aug. 31, 2022. The entire disclosures of this application is incorporated by reference herein.

### BACKGROUND

The present disclosure relates to a semiconductor integrated circuit device, and more particularly to a layout configuration of an IO cell provided with an input/output circuit for exchanging signals with the outside of the semiconductor integrated circuit device.

The I/O cell, constituting a semiconductor integrated circuit device, for exchanging signals with the outside of the semiconductor integrated circuit device is generally provided with an output buffer and an electrostatic discharging (ESD) protection circuit. Also, with the recent miniaturization of the semiconductor integrated circuit device, demands for speedup are increasingly growing.

WO 2013/038616 discloses an example of the layout structure of an ESD protection circuit provided in a semiconductor integrated circuit device. In this layout structure, in order to reduce the terminal capacitance at a signal terminal in the ESD circuit for achieving speedup, the diffusion region connected to the signal terminal is split, and also the distance between an interconnect connected to the signal terminal and an interconnect connected to a power supply terminal is made large.

With the miniaturization of the semiconductor integrated circuit device, the number of metal interconnect layers is increasing, and along with this, the distance between interconnect layers is becoming small. For this reason, not only the parasitic capacitance between interconnects in the same layer, but also the parasitic capacitance between different interconnect layers are increasing.

An objective of the present disclosure is presenting a layout structure of an IO cell including interconnects of multiple layers, in which the terminal capacitance at a signal terminal is reduced, in a semiconductor integrated circuit device.

### SUMMARY

According to the first mode of the disclosure, a semiconductor integrated circuit device includes a plurality of IO cells, wherein at least one of the plurality of IO cells includes an output circuit, the output circuit includes an external output terminal, a protective resistance connected to the external output terminal at one end, and an output transistor connected between the other end of the protective resistance and a first power supply, the output transistor includes a first transistor row including a plurality of transistors arranged in a first direction, and a second transistor row including a plurality of transistors arranged in the first direction, the second transistor row being adjacent to the first transistor row in a second direction perpendicular to the first direction, each of the transistors of the first and second transistor rows has a gate extending in the second direction, a source connected to the first power supply, and a drain connected to the other end of the protective resistance, the output circuit includes a first interconnect extending in the first direction in a first interconnect layer between the first transistor row and the second transistor row, and connected to the gates of the transistors of the first and second transistor rows, a second interconnect extending in the second direction in a second interconnect layer located one layer above the first interconnect layer, and connected to the drains of the transistors of the first transistor row, and a third interconnect extending in the second direction in the second interconnect layer, and connected to the drains of the transistors of the second transistor row, and the first interconnect is located between the second and third interconnects separated from each other in planar view.

According to the above mode, an IO cell includes an output circuit having a protective resistance and an output transistor. The output transistor includes first and second transistor rows each including a plurality of transistors arranged in the first direction. Each of the transistors of the first and second transistor rows has a gate extending in the second direction, a source connected to a first power supply, and a drain connected to the other end of the protective resistance. In a first interconnect layer, a first interconnect connected to the gates of the transistors is placed between the first and second transistor rows. In a second interconnect layer, a second interconnect connected to the drains of the transistors of the first transistor row and a third interconnect connected to the drains of the transistors of the second transistor row are placed. The first interconnect is located between the second and third interconnects separated from each other in planar view. That is, the second and third interconnects connected to the drains of the transistors do not overlap the first interconnect connected to the gates of the transistors in planar view. Since this reduces the parasitic capacitance at the node of the output transistor connected the other end of the protective resistance, speedup of the circuit can be achieved.

According to the second mode of the disclosure, a semiconductor integrated circuit device includes a plurality of IO cells, wherein at least one of the plurality of IO cells includes an output circuit, the output circuit includes an external output terminal, an electrostatic discharge (ESD) protection diode having a first node connected to the external output terminal and a second node connected to a first power supply, a first interconnect extending in a first direction in a first interconnect layer, and connected to the first node of the ESD protection diode, second and third interconnects extending in the first direction in the first interconnect layer, connected to the second node of the ESD protection diode, and placed on both sides of the first interconnect in a second direction perpendicular to the first direction, a fourth interconnect extending in the first direction in a second interconnect layer one layer above the first interconnect layer, overlapping the first interconnect in planar view, and connected to the first interconnect, a fifth interconnect in the second interconnect layer, overlapping the second interconnect in planar view, and connected to the second interconnect, a sixth interconnect in the second interconnect layer, overlapping the third interconnect in planar view, and connected to the third interconnect, a seventh interconnect placed in a third interconnect layer, and connected to the fourth interconnect, an eighth interconnect placed in the third interconnect layer, overlapping the fifth interconnect in planar view, and connected to the fifth interconnect, and a ninth interconnect placed in the third interconnect layer, overlapping the sixth interconnect in planar view, and connected to the sixth interconnect, and the fourth interconnect is located between the eighth interconnect and the ninth interconnect separated from each other in planar view.

According to the above mode, an IO cell includes an output circuit having an ESD protection diode. In a first interconnect layer, a first interconnect extending in the first direction and connected to the first node of the ESD protection diode is placed, and second and third interconnects extending in the first direction and connected to the second node of the ESD protection diode are placed on both sides of the first interconnect in the second direction. In a second interconnect layer, a fourth interconnect extending in the first direction and connected to the first interconnect is placed, and fifth and sixth interconnects respectively connected to the second and third interconnects are placed. In a third interconnect layer, a seventh interconnect connected to the fourth interconnect is placed, and eighth and ninth interconnects respectively connected to the fifth and sixth interconnects are placed. The fourth interconnect is located between the eighth and ninth interconnects separated from each other in planar view. That is, the fourth interconnect connected to the first node of the ESD protection diode does not overlap the eighth or ninth interconnect connected to the second node of the ESD protection diode in planar view. Since this reduces the parasitic capacitance at the first node of the ESD protection diode connected to the external output terminal, speedup of the circuit can be achieved.

According to the third mode of the disclosure, a semiconductor integrated circuit device includes a plurality of IO cells, wherein at least one of the plurality of IO cells includes an output circuit, the output circuit includes an external output terminal, a protective resistance connected to the external output terminal at one end, and an output transistor connected between the other end of the protective resistance and a first power supply, the output transistor includes a plurality of transistors arranged in a first direction, each of the plurality of transistors has a gate extending in a second direction perpendicular to the first direction, a source connected to the first power supply, and a drain connected to the other end of the protective resistance, the output circuit includes a first interconnect extending in the second direction in a first interconnect layer, and connected to the drains of some of the plurality of transistors, second and third interconnects extending in the second direction in the first interconnect layer, placed on both sides of the first interconnect in the first direction, and connected to the sources of some of the plurality of transistors, a fourth interconnect extending in the second direction in a second interconnect layer one layer above the first interconnect layer, overlapping the first interconnect in planar view, and connected to the first interconnect, a fifth interconnect in the second interconnect layer, overlapping the second interconnect in planar view, and connected to the second interconnect, a sixth interconnect in the second interconnect layer, overlapping the third interconnect in planar view, and connected to the third interconnect, a seventh interconnect placed in a third interconnect layer, and connected to the fourth interconnect, an eighth interconnect placed in the third interconnect layer, overlapping the fifth interconnect in planar view, and connected to the fifth interconnect, and a ninth interconnect placed in the third interconnect layer, overlapping the sixth interconnect in planar view, and connected to the sixth interconnect, and the fourth interconnect is located between the eighth interconnect and the ninth interconnect separated from each other in planar view.

According to the above mode, an IO cell includes an output circuit having a protective resistance and an output transistor. The output transistor includes a plurality of transistors arranged in the first direction, and each of the transistors has a gate extending in the second direction, a source connected to a first power supply, and a drain connected to the other end of the protective resistance. In a first interconnect layer, a first interconnect extending in the second direction and connected to the drains of the transistors is formed, and second and third interconnects connected to the sources of the transistors are placed on both sides of the first interconnect in the first direction. In a second interconnect layer, a fourth interconnect extending in the second direction and connected to the first interconnect is placed, and fifth and sixth interconnects respectively connected to the second and third interconnects are placed. In a third interconnect layer, a seventh interconnect connected to the fourth interconnect is placed, and eighth and ninth interconnects respectively connected to the fifth and sixth interconnects are placed. The fourth interconnect is located between the eighth interconnect and the ninth interconnect separated from each other in planar view. That is, the fourth interconnect connected to the drains of the transistors does not overlap the eighth or ninth interconnect connected to the sources of the transistors in planar view. Since this reduces the parasitic capacitance at the node of the output transistor connected to the other end of the protective resistance, speedup of the circuit can be achieved.

According to the present disclosure, in a semiconductor integrated circuit device, since the parasitic capacitance at a signal terminal is reduced in an output circuit included in an IO cell, speedup of the circuit can be achieved.

### BRIEF DESCRIPTION OF THE DRAWINGS

FIG. 1 is a plan view schematically showing the entire configuration of a semiconductor integrated circuit device according to an embodiment.

FIG. 2 is a circuit configuration diagram of an output circuit according to the first embodiment.

FIG. 3 shows an overview example of an IO cell layout in the first embodiment.

FIG. 4 is a plan view showing details of the IO cell layout of FIG. 3

FIG. 5 is a plan view showing details of the IO cell layout of FIG. 3

FIG. 6 is a plan view showing details of the IO cell layout of FIG. 3

FIG. 7 is a plan view showing details of the IO cell layout of FIG. 3

FIG. 8 is a plan view showing details of the IO cell layout of FIG. 3

FIG. 9 is a plan view showing details of the IO cell layout of FIG. 3

FIG. 10 is a plan view showing details of the IO cell layout of FIG. 3

FIG. 11 is a plan view showing details of the IO cell layout of FIG. 3

FIG. 12 is a plan view showing details of an IO cell layout according to Alteration 1.

FIG. 13 is a plan view showing details of the IO cell layout according to Alteration 1.

FIG. 14 is a plan view showing details of an IO cell layout according to Alteration 2.

FIG. 15 is a plan view showing details of the IO cell layout according to Alteration 2.

FIG. 16 is a plan view showing details of an IO cell layout according to Alteration 3.

FIG. 17 is a plan view showing details of the IO cell layout according to Alteration 3.

FIG. 18 is a circuit configuration diagram of an output circuit according to the second embodiment.

FIG. 19 shows an overview example of an IO cell layout in the second embodiment.

FIG. 20A is a plan view showing details of the IO cell layout of FIG. 19.

FIG. 20B is a plan view showing details of the IO cell layout of FIG. 19.

FIG. 21 is a plan view showing details of the IO cell layout of FIG. 19.

FIG. 22 is a plan view showing details of the IO cell layout of FIG. 19.

FIG. 23 shows an overview example of an IO cell layout in an alteration of the second embodiment.

FIG. 24 shows an overview example of an IO cell layout in another alteration of the second embodiment.

### DETAILED DESCRIPTION

Embodiments of the present disclosure will be described hereinafter with reference to the accompanying drawings. In the following description, “VDDIO” and “VSS” are assumed to indicate power supply voltages or power supplies themselves. It is also assumed that transistors are formed on a P-substrate or an N-well. Note however that transistors may be formed on a P-well or formed on an N-substrate.

### First Embodiment

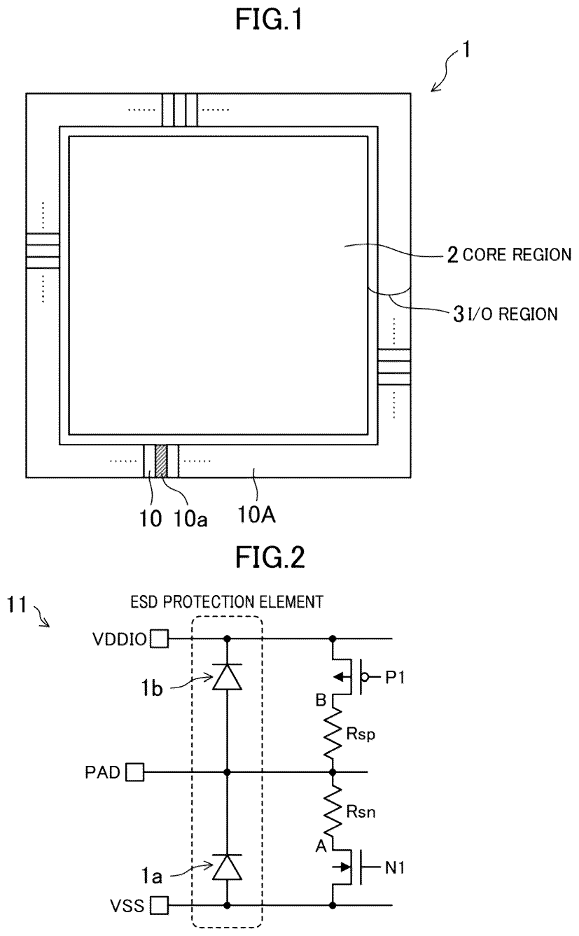

FIG. 1 is a plan view schematically showing the entire configuration of a semiconductor integrated circuit device according to an embodiment. The semiconductor integrated circuit device 1 shown in FIG. 1 includes: a core region 2 in which internal core circuits are formed; and an IO region 3 provided between the core region 2 and the chip edges, in which interface circuits (IO circuits) are formed. An IO cell row 10A is provided in the IO region 3 to encircle the peripheral portion of the semiconductor integrated circuit device 1. Although illustration is simplified in FIG. 1, a plurality of IO cells 10 constituting interface circuits are arranged in line in the IO cell row 10A. Also, although illustration is omitted in FIG. 1, a plurality of external connection pads are placed in the semiconductor integrated circuit device 1. Note that the IO cell row 10A may be provided partly in the peripheral portion of the semiconductor integrated circuit device 1.

The IO cells 10 include signal IO cells and power IO cells. The signal IO cells include circuits required for exchanging signals with the outside of the semiconductor integrated circuit device 1 or with the core region 2, such as a level shifter circuit, an output buffer circuit, and a circuit for ESD protection. The power IO cells, which supply power fed to the external connection pads to the inside of the semiconductor integrated circuit device 1, include a circuit for ESD protection, for example.

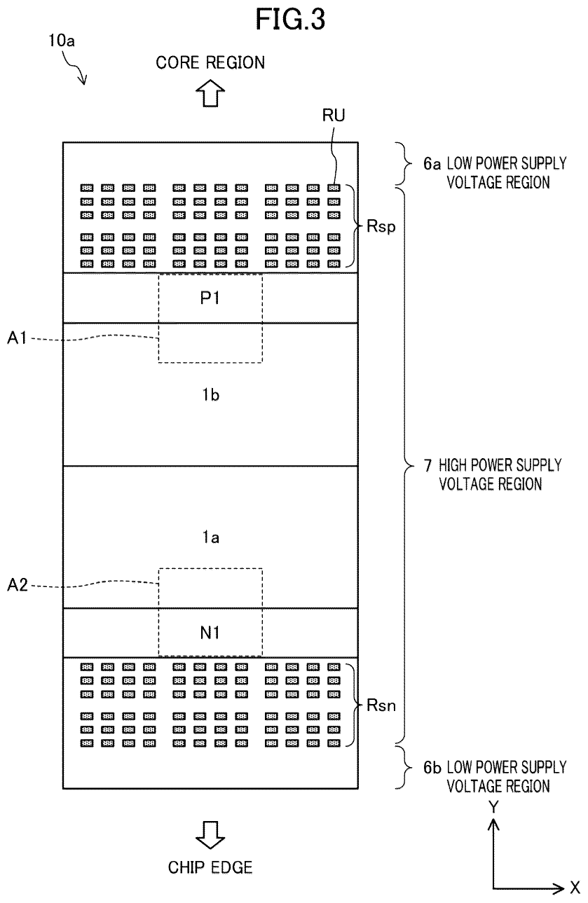

FIG. 2 is a circuit configuration diagram of an output circuit 11 included in the IO cells 10. Note that, although an actual output circuit includes circuit elements other than those shown in FIG. 2, such elements are omitted in FIG. 2.

The output circuit 11 shown in FIG. 2 includes an external output terminal PAD, output transistors P1 and N1, electrostatic discharge (ESD) protection diodes 1a and 1b, and protective resistances Rsn and Rsp. The output transistor P1 is a p-type transistor and the output transistor N1 is an n-type transistor.

The output transistors P1 and N1 output signals to the external output terminal PAD according to signals received at their gates. The output transistor P1 is connected to VDDIO at its source and to the external output terminal PAD at its drain through the protective resistance Rsp. The output transistor N1 is connected to VSS at its source and to the external output terminal PAD at its drain through the protective resistance Rsn. In this embodiment, the protective resistances Rsp and Rsn are each constituted by a plurality of resistor elements formed in an interconnect layer that is formed in the back end of line (BEOL: interconnect process). Note that the node between the output transistor N1 and the protective resistance Rsn is herein called node A and the node between the output transistor Pl and the protective resistance Rsp is called node B.

The ESD protection diode 1a is provided between VSS and the external output terminal PAD, with its anode connected to VSS and its cathode connected to the external output terminal PAD. The ESD protection diode 1b is provided between VDDIO and the external output terminal PAD, with its anode connected to the external output terminal PAD and its cathode connected to VDDIO. When high-voltage noise is input into the external output terminal PAD, a current flows to VDDIO and VSS through the ESD protection diodes 1a and 1b, whereby the output transistors P1 and N1 are protected.

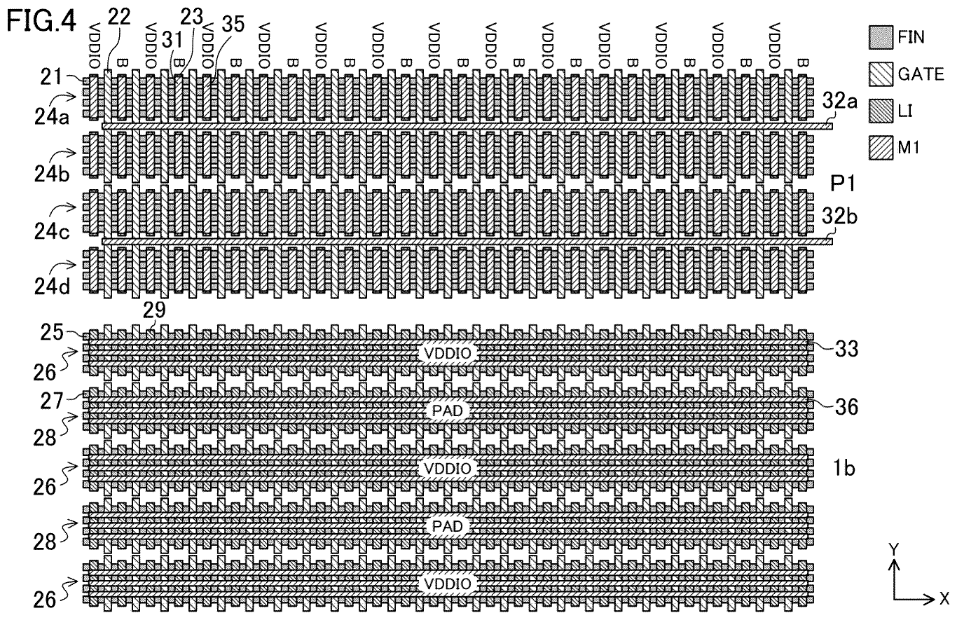

FIG. 3 shows an overview example of the layout of an IO cell. The layout of FIG. 3 corresponds to an IO cell 10a, one of the IO cells 10 arranged along the lower edge of the semiconductor integrated circuit device 1 in FIG. 1. Note herein that the X direction (corresponding to the first direction) is the direction along an outer edge of the semiconductor integrated circuit device 1, along which a plurality of IO cells 10 are arranged, and the Y direction (corresponding to the second direction) is the direction perpendicular to the X direction.

The IO cell generally includes: a high power supply voltage region including a circuit for ESD protection and an output buffer for outputting a signal to the outside of the semiconductor integrated circuit device; and a low power supply voltage region including a circuit for inputting/outputting a signal into/from the inside of the semiconductor integrated circuit device. The IO cell 10a of FIG. 3 has two low power supply voltage regions 6a and 6b and a high power supply voltage region 7 separated from one another in the Y direction. The low power supply voltage region 6a is located closer to the core region 2 and the low power supply voltage region 6b is located closer to the chip edge. The high power supply voltage region 7 is located between the low power supply voltage region 6a and the low power supply voltage region 6b.

The low power supply voltage region 6a, located near the output transistor P1, includes a circuit that generates a signal input into the gate of the output transistor P1, for example. The low power supply voltage region 6b, located near the output transistor N1, includes a circuit that generates a signal input into the gate of the output transistor N1, for example.

The IO cell 10a shown in FIG. 3 constitutes the output circuit 11 of FIG. 2. In the high power supply voltage region 7, the output transistor N1, the ESD protection diode 1a, the ESD protection diode 1b, and the output transistor P1 are formed in this order from the chip edge. Resistor elements RU are arranged in an array in the X-Y directions above portions of the high power supply voltage region 7 other than the portions where the output transistor N1, the ESD protection diode 1a, the ESD protection diode 1b, and the output transistor P1 are placed. The resistor elements RU placed above the portion near the output transistor P1 are mutually connected to constitute the protective resistance Rsp. The resistor elements RU placed above the portion near the output transistor N1 are mutually connected to constitute the protective resistance Rsn.

The protective resistance Rsp is connected between the external output terminal PAD and the node B, and interconnects corresponding to the node B extend from the region in which the protective resistance Rsp is formed to the region in which the output transistor P1 is placed. The protective resistance Rsn is connected between the external output terminal PAD and the node A, and interconnects corresponding to the node A extend from the region in which the protective resistance Rsn is formed to the region in which the output transistor N1 is placed.

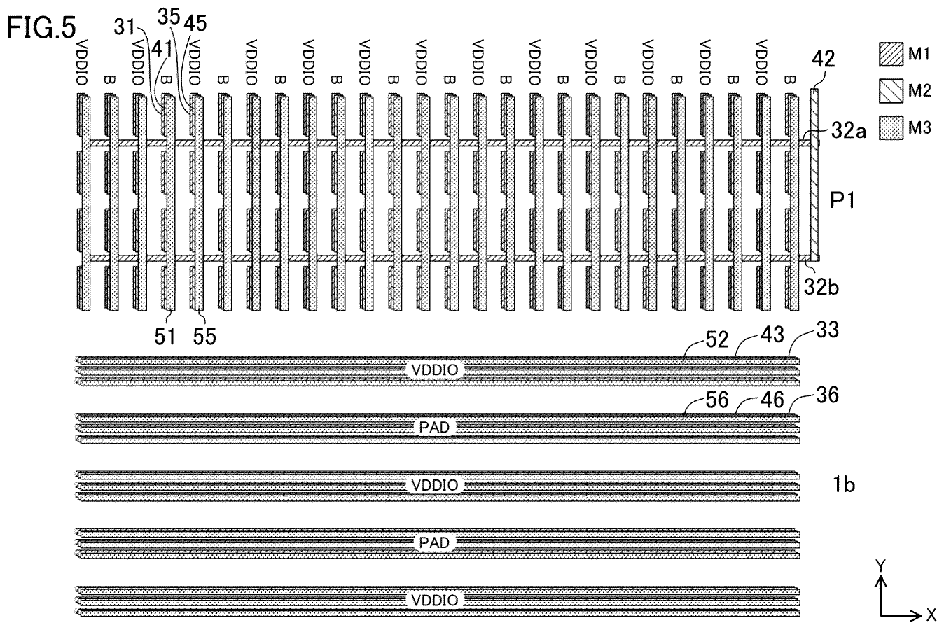

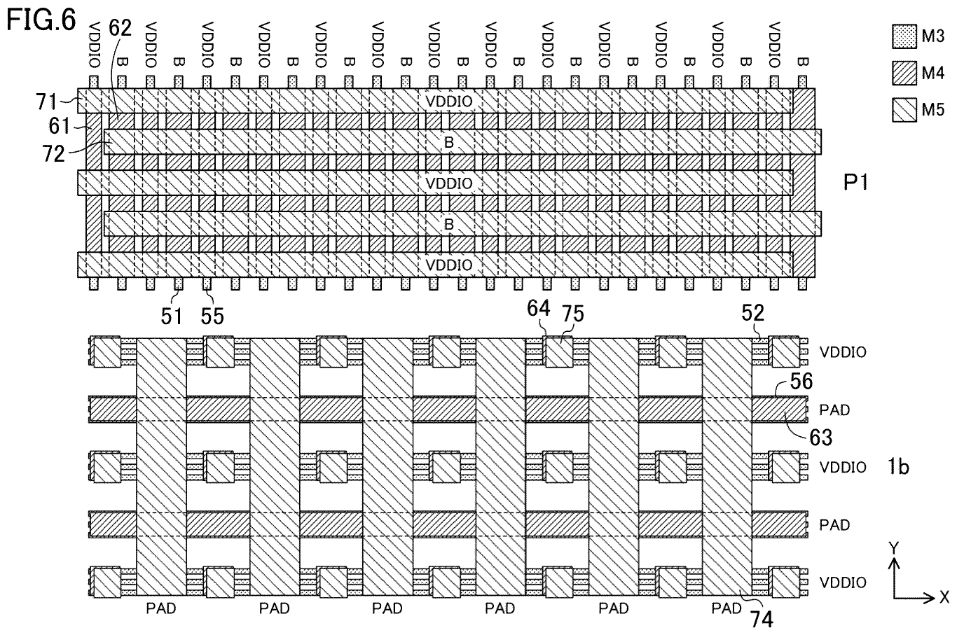

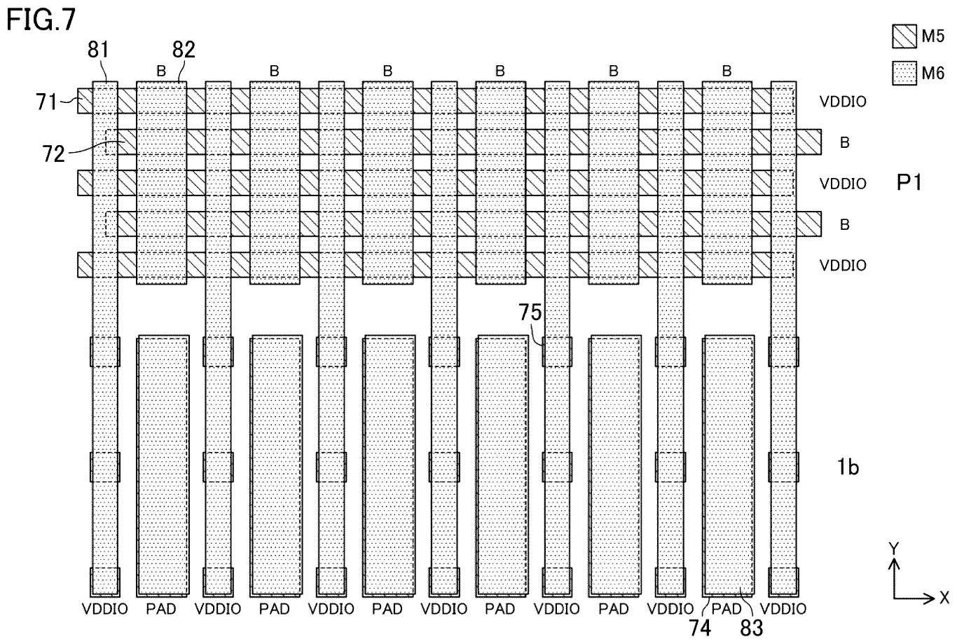

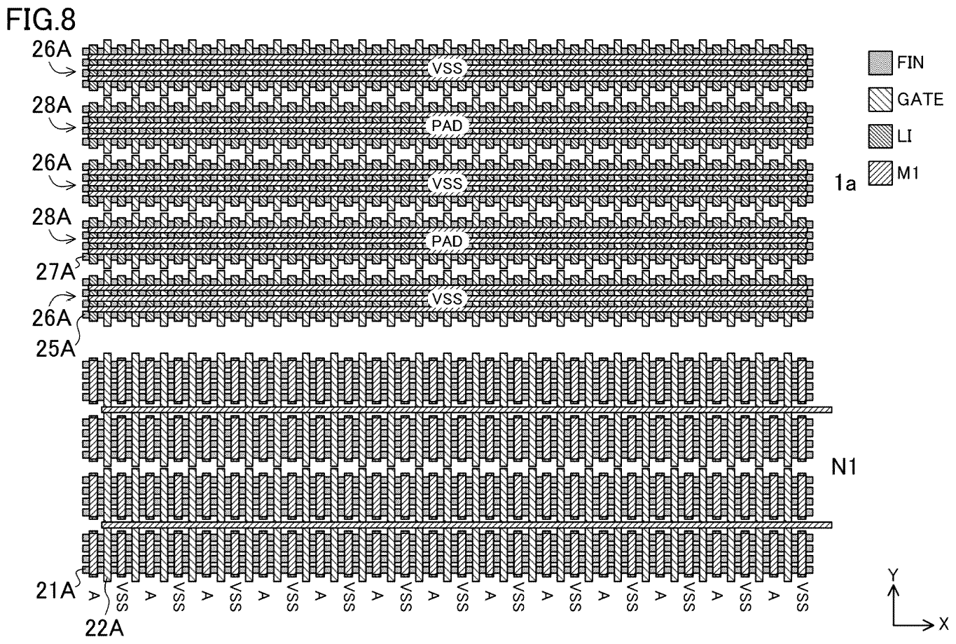

FIGS. 4 to 7 are plan views showing details of the layout of the IO cell. All of FIGS. 4 to 7 show planar structures of part A1 in FIG. 3, i.e., the region in which the output transistor P1 and the ESD protection diode 1b are placed. FIG. 4 shows the structure below an M1 interconnect layer, FIG. 5 shows the structure of M1 to M3 interconnect layers, FIG. 6 shows the structure of M3 to M5 interconnect layers, and FIG. 7 shows the structure of M5 to M6 interconnect layers.

As shown in FIG. 4, in the region of the output transistor P1, formed are a plurality of p-type fins 21 that extend in the X direction and are arranged in the Y direction and a plurality of gate interconnects 22 that extend in the Y direction and are arranged in the X direction. Transistors are formed by the fins 21 and the gate interconnects 22 overlapping each other in planar view. In FIG. 4, each transistor has four fins 21.

The transistors are arranged in line in the X direction so that their sources and drains lie alternately. In FIG. 4, transistor rows 24a, 24b, 24c, and 24d each including a plurality of transistors arranged in line in the X direction are arranged in the Y direction. The transistor rows 24a and 24b share the gate interconnects 22, and the transistor rows 24c and 24d share the gate interconnects 22.

Local interconnects (LI) 23 extending in the Y direction are placed at the positions of the fins 21 that are to be the sources or drains of the transistors. The fins 21 and the local interconnects 23 are in contact with each other at the positions intersecting each other in planar view. At the positions overlapping the local interconnects 23 in planar view, M1 interconnects 31 and 35 extending in the Y direction are formed in a first metal layer (M1 interconnect layer). The local interconnects 23 and the overlying M1 interconnects 31 and 35 are mutually connected through contacts (not shown). The M1 interconnects 35 connected to the positions of the fins 21 that are to be the sources of the transistors are connected to VDDIO, and the M1 interconnects 31 connected to the positions of the fins 21 that are to be the drains of the transistors are connected to the node B.

In the M1 interconnect layer, M1 interconnects 32a and 32b extending in the X direction are formed. The M1 interconnect 32a is placed between the transistor rows 24a and 24b, and the M1 interconnect 32b is placed between the transistor rows 24c and 24d. The M1 interconnects 32a and 32b intersect with the gate interconnects 22 in planar view and are connected to the gate interconnects 22 through contacts (not shown). The M1 interconnects 32a and 32b transmit a control signal to be given to the gates of the output transistor P1. This control signal is generated in a control circuit located above the output transistor P1 as viewed in the figure, and supplied to the gates of the transistors constituting the output transistor P1 through the M1 interconnects 32a and 32b.

In the region of the ESD protection diode 1b, cathode portions 28 each formed of n-type fins 25 and anode portions 28 each formed of p-type fins 27 are provided. The fins 25 and 27 extend in the X direction. Diodes are formed between the n-type fins 25 and the p-type fins 27.

As in the region of the output transistor P1, local interconnects (LI) 29 extending in the Y direction are placed for the fins 25 and 27. The fins 25 and 27 and the local interconnects 29 are in contact with each other at the positions intersecting each other in planar view. Also, M1 interconnects 33 and 36 extending in the X direction are placed in the M1 interconnect layer. The M1 interconnects 33 placed in the cathode portions 26 are connected to VDDIO, and the M1 interconnects 36 placed in the anode portions 28 are connected to the external output terminal PAD. The local interconnects 29 and the M1 interconnects 33 and 36 are mutually connected through contacts (not shown) at the positions intersecting each other in planar view.

As shown in FIG. 5, in the region of the output transistor P1, M2 interconnects 41 and 45 extending in the Y direction are formed in a second metal layer (M2 interconnect layer) at positions overlapping the M1 interconnects 31 and 35 in planar view. The M1 interconnects 31 and the overlying M2 interconnects 41 are mutually connected through contacts (not shown). The M1 interconnects 35 and the overlying M2 interconnects 45 are mutually connected through contacts (not shown).

The M1 interconnects 32a and 32b extending in the X direction are connected to an M2 interconnect 42 located on the right end in the figure. The M2 interconnect 42 is connected to the control circuit located above in the figure.

M3 interconnects 51 extending in the Y direction are formed in a third metal layer (M3 interconnect layer) at the same positions as the M1 interconnects 31 and the M2 interconnects 41 in the X direction. M3 interconnects 55 extending in the Y direction are formed in the M3 interconnect layer at the same positions as the M1 interconnects 35 and the M2 interconnects 45 in the X direction. The M3 interconnects 51 are each formed to lie over the entire four M2 interconnects 41 arranged in the Y direction in planar view. The M3 interconnects 55 are each formed to lie over the entire four M2 interconnects 45 arranged in the Y direction in planar view. The M2 interconnects 41 and the overlying M3 interconnects 51 are connected through contacts (not shown). The M2 interconnects 45 and the overlying M3 interconnects 55 are connected through contacts (not shown).

The M2 interconnects 41 for the transistor rows 24a and the M2 interconnects 41 for the transistor rows 24b are separated from each other in the Y direction. The M1 interconnect 32a extending in the X direction is located between the M2 interconnects 41 for the transistor rows 24a and the M2 interconnects 41 for the transistor rows 24b. Also, the M2 interconnects 41 for the transistor rows 24c and the M2 interconnects 41 for the transistor rows 24d are separated from each other in the Y direction. The M1 interconnect 32b extending in the X direction is located between the M2 interconnects 41 for the transistor rows 24c and the M2 interconnects 41 for the transistor rows 24d. That is, the M2 interconnects 41 extending in the Y direction, which are connected to the node B, do not overlap the M1 interconnect 32a or 32b extending in the X direction, which is connected to the gate interconnects 22 of the transistors, in planar view. Since this reduces the parasitic capacitance related to the node B, speedup can be achieved.

Note that, in FIG. 5, the M2 interconnects 45 connected to VDDIO do not overlap the M1 interconnect 32a or 32b in planar view, either. However, even if the M2 interconnects 45 connected to VDDIO overlap the M1 interconnects 32a or 32b in planar view, they won't increase the parasitic capacitance related to node B. Therefore, like the M3 interconnects 55, the M2 interconnects 45 connected to VDDIO may each be formed to lie over the entire four M1 interconnects 35 arranged in the Y direction in planar view.

In the region of the ESD protection diode 1b, M2 interconnects 43 extending in the X direction are formed in the M2 interconnect layer at positions overlapping the M1 interconnects 33 in planar view. The M1 interconnects 33 and the overlying M2 interconnects 43 are mutually connected through contacts (not shown). Also, M2 interconnects 46 extending in the X direction are formed in the M2 interconnect layer at positions overlapping the M1 interconnects 36 in planar view. The M1 interconnects 36 and the overlying M2 interconnects 46 are mutually connected through contacts (not shown).

M3 interconnects 52 extending in the X direction are formed in the M3 interconnect layer at positions overlapping the M2 interconnects 43 in planar view. The M2 interconnects 43 and the overlying M3 interconnects 52 are mutually connected through contacts (not shown). Also, M3 interconnects 56 extending in the X direction are formed in the M3 interconnect layer at positions overlapping the M2 interconnects 46 in planar view. The M2 interconnects 46 and the overlying M3 interconnects 56 are mutually connected through contacts (not shown).

As shown in FIG. 6, in the region of the output transistor P1, M4 interconnects 61 and 62 extending in the Y direction are formed in a fourth metal layer (M4 interconnect layer). The M4 interconnects 61 connected to VDDIO overlap the M3 interconnects 55 in planar view and are connected to the M3 interconnects 55 through contacts (not shown). The M4 interconnects 62 connected to the node B overlap the M3 interconnects 51 in planar view and are connected to the M3 interconnects 51 through contacts (not shown).

M5 interconnects 71 and 72 extending in the X direction are formed in a fifth metal layer (M5 interconnect layer). The M5 interconnects 71 connected to VDDIO are connected to the M4 interconnects 61 through contacts (not shown). The M5 interconnects 72 connected to the node B are connected to the M4 interconnects 62 through contacts (not shown).

Note that, in the region of the output transistor P1, the directions of extension of the interconnects in the M4 and M5 interconnect layers are not limited to those shown in FIG. 6.

In the region of the ESD protection diode 1b, M4 interconnects 63 extending in the X direction are formed in the M4 interconnect layer. The M4 interconnects 63 connected to the external output terminal PAD overlap the M3 interconnects 56 in planar view and are connected to the M3 interconnects 56 through contacts (not shown).

M5 interconnects 74 extending in the Y direction are formed in the M5 interconnect layer. The M5 interconnects 74 connected to the external output terminal PAD are connected to the M4 interconnects 63 in their overlap portions in planar view through contacts (not shown).

Also, M4 interconnects 64 and M5 interconnects 75 are placed at positions overlapping the M3 interconnects 52 in planar view in a dotted manner. That is, the M4 interconnects 64 and the M5 interconnects 75 overlapping each other in planar view are formed above the M3 interconnects 52 at positions between the adjacent M5 interconnects 74 extending in the Y direction. The M4 interconnects 64 are connected to the underlying M3 interconnects 52 through contacts (not shown), and the M5 interconnects 75 are connected to the underlying M4 interconnects 64 through contacts (not shown).

As shown in FIG. 7, in the region of the output transistor P1, M6 interconnects 81 and 82 extending in the Y direction are formed in a sixth metal layer (M6 interconnect layer). The M6 interconnects 81 connected to VDDIO are connected to the M5 interconnects 71 through contacts (not shown). The M6 interconnects 82 connected to the node B are connected to the M5 interconnects 72 through contacts (not shown). The M6 interconnects 82 are connected to the protective resistance Rsp.

In the region of the ESD protection diode 1b, M6 interconnects 83 extending in the Y direction are formed in the M6 interconnect layer. The M6 interconnects 83 connected to the external output terminal PAD overlap the M5 interconnects 74 in planar view and are connected to the M5 interconnects 74 through contacts (not shown). Also, the M6 interconnects 81, extending from the region of the transistor P1 to the region of the ESD protection diode 1b, overlap the M5 interconnects 75 in planar view and are connected to the M5 interconnects 75 through contacts (not shown).

In the region of the ESD protection diode 1b, the M4 interconnects 63 that extend in the X direction and are connected to the external output terminal PAD overlap only the M3 interconnects 56 connected to the external output terminal PAD in planar view as for the M3 interconnect layer. Also, the M4 interconnects 63 are located between the M5 interconnects 75 arranged in the Y direction and separated from each other in planar view, and overlap only the M5 interconnects 74 connected to the external output terminal PAD as for the M5 interconnect layer. Therefore, no parasitic capacitance at the M4 interconnects 63 occurs between the M3-M4 interconnect layers or between the M4-M5 interconnect layers. Since this reduces the parasitic capacitance related to the external output terminal PAD, speedup can be achieved.

Also, the M5 interconnects 74 that extend in the Y direction and are connected to the external output terminal PAD are located between the M4 interconnects 64 arranged in the X direction and separated from each other in planar view, and overlap only the M4 interconnects 63 connected to the external output terminal PAD as for the M4 interconnect layer. Also, the M5 interconnects 74 overlap only the M6 interconnects 83 connected to the external output terminal PAD in planar view as for the M6 interconnect layer. Therefore, no parasitic capacitance at the M5 interconnects 74 occurs between the M4-M5 interconnect layers or between the M5-M6 interconnect layers. Since this reduces the parasitic capacitance related to the external output terminal PAD, speedup can be achieved.

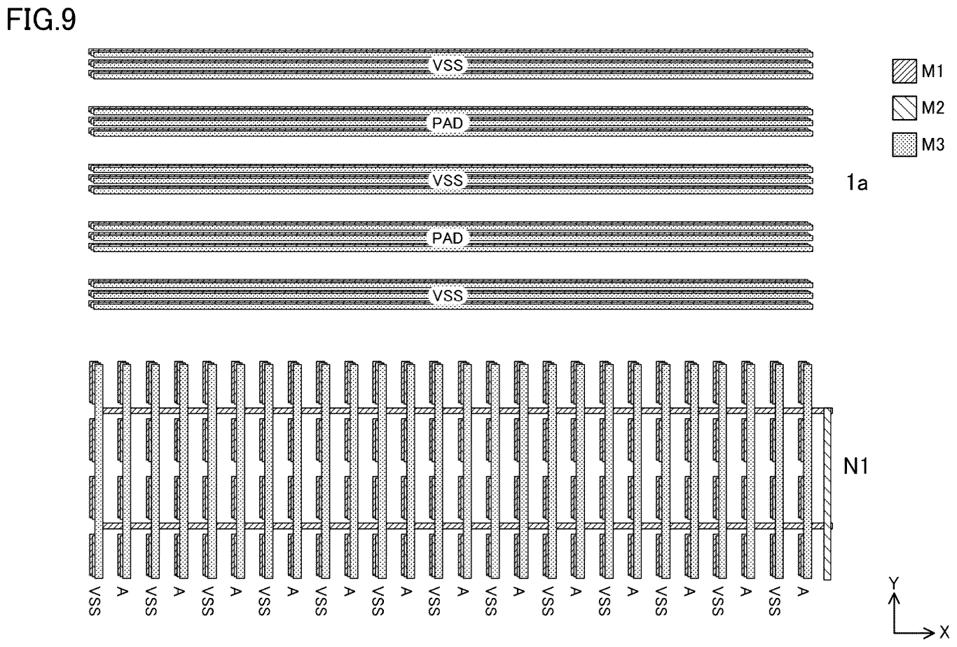

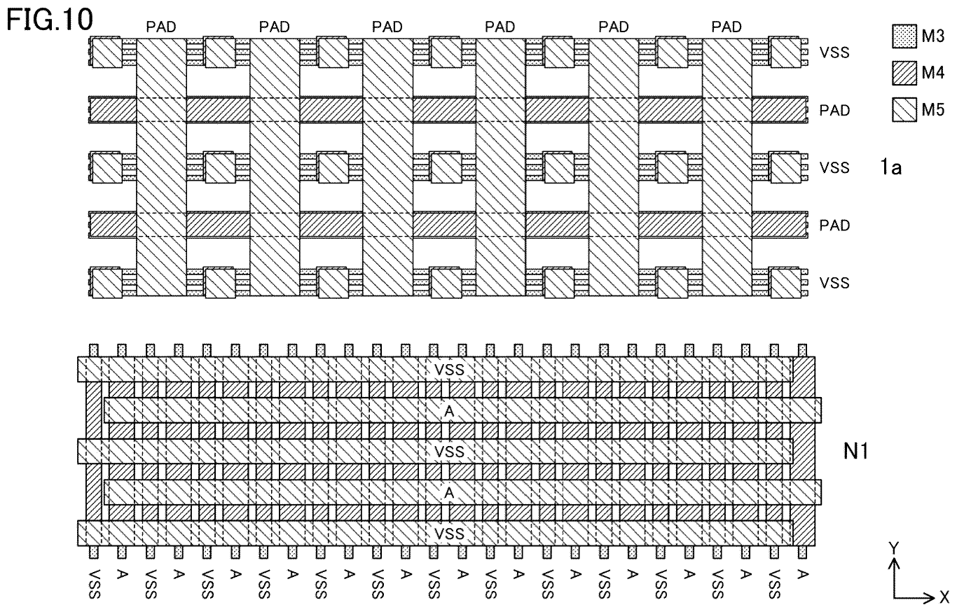

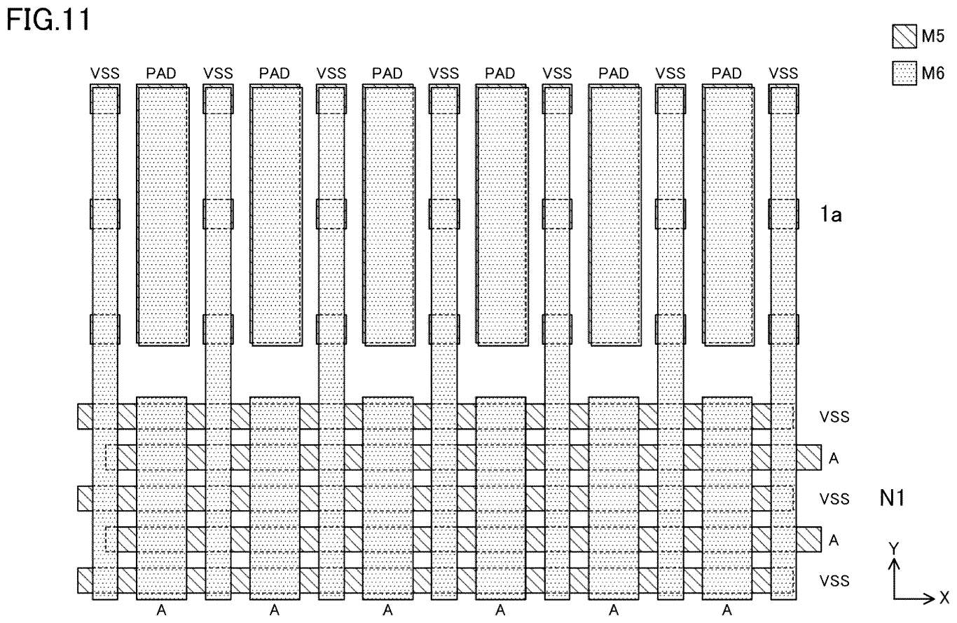

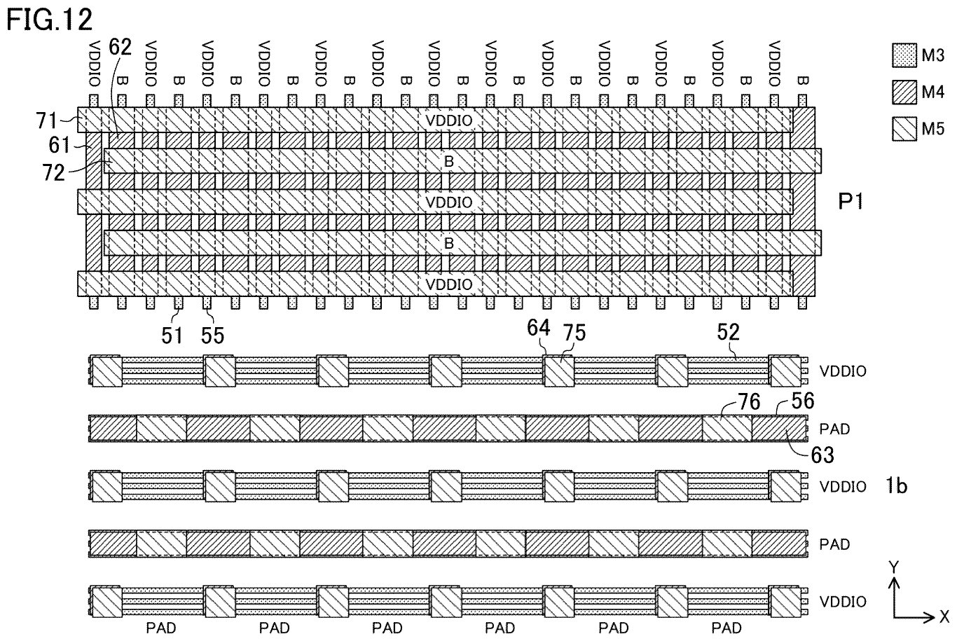

FIGS. 8 to 11 are plan views showing details of the layout of the IO cell. All of FIGS. 8 to 11 show planar structures of part A2 in FIG. 3, i.e., the region in which the output transistor N1 and the ESD protection diode 1a are placed. FIG. 8 shows the structure below the M1 interconnect layer, FIG. 9 shows the structure of the M1 to M3 interconnect layers, FIG. 10 shows the structure of the M3 to M5 interconnect layers, and FIG. 11 shows the structure of the M5 to M6 interconnect layers.

The layouts of FIGS. 8 to 11 correspond to ones inverted vertically (in the Y direction) from the layouts of FIGS. 4 to 7, in which VDDIO is replaced with VSS and the node B with the node A. Since the layouts of FIGS. 8 to 11 are easily understandable from the description on the layouts of FIGS. 4 to 7, detailed description thereof is omitted here.

As shown in FIG. 8, in the region of the output transistor N1, formed are a plurality of n-type fins 21A that extend in the X direction and are arranged in the Y direction and a plurality of gate interconnects 22A that extend in the Y direction and are arranged in the X direction. Transistors are formed by the fins 21A and the gate interconnects 22A overlapping each other in planar view.

In the region of the ESD protection diode 1a, anode portions 26A each formed of p-type fins 25A and cathode portions 28A each formed of n-type fins 27A and are provided. The fins 25A and 27A extend in the X direction. The anode portions 26A are connected to VSS, and the cathode portions 28A are connected to the external output terminal PAD. Diodes are formed between the p-type fins 25A and the n-type fins 27A.

Since the placement of interconnects in the configurations of FIGS. 8 to 11 can be easily known by analogy from the description on the configurations of FIGS. 4 to 7, detailed description thereof is omitted here. In the configurations of FIGS. 8 to 11, also, effects similar to those in the configurations of FIGS. 4 to 7 are obtained.

As described above, according to this embodiment, the following effects are obtained. That is, in the configurations of FIGS. 4 to 7, for example, in the M1 interconnect layer, the M1 interconnect 32a connected to the gates of the transistors is placed between the transistor rows 24a and 24b. In the M2 interconnect layer, placed are the M2 interconnects 41 provided for the transistor row 24a and connected to the node B and the M2 interconnects 41 provided for the transistor row 24b and connected to the node B. The M1 interconnect 32a is located between the M2 interconnects 41 separated from each other in planar view. That is, the M2 interconnects 41 connected to the node B do not overlap the M1 interconnect 32a connected to the gates of the transistors. This also applies to the configurations of FIGS. 8 to 11. Therefore, since the parasitic resistances at the node B of the output transistor P1 and at the node A of the output transistor N1 are reduced, speedup of the circuit can be achieved.

Also, in the configurations of FIGS. 4 to 7, for example, in the M4 interconnect layer, the M4 interconnects 63 that extend in the X direction and are connected to the anode portions 28 of the ESD protection diode 1b are placed, and on both sides of the M4 interconnects 63 in the Y direction, the M4 interconnects 64 connected to the cathode portions of the ESD protection diode 1b are placed. In the M5 interconnect layer, the M5 interconnects 74 connected to the M4 interconnects 63 are placed, and the M5 interconnects 75 connected to the M4 interconnects 64 are placed. The M4 interconnects 63 are located between the M5 interconnects 75 arranged in the Y direction and separated from each other. That is, the M4 interconnects 63 connected to the external output terminal PAD do not overlap the M5 interconnects 75 connected to VDDIO in planar view. This also applies to the configurations of FIGS. 8 to 11. Therefore, since the parasitic resistances at the anode portions 28 of the ESD protection diode 1b, and at the cathode portions 28A of the ESD protection diode 1a, both connected to the external output terminal PAD, are reduced, speedup of the circuit can be achieved.

### (Alteration 1)

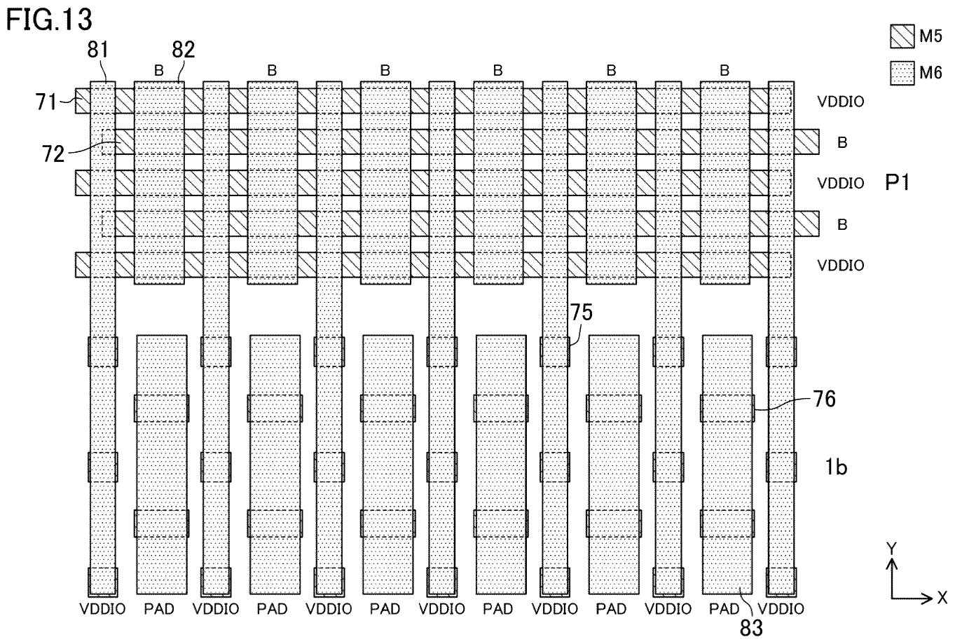

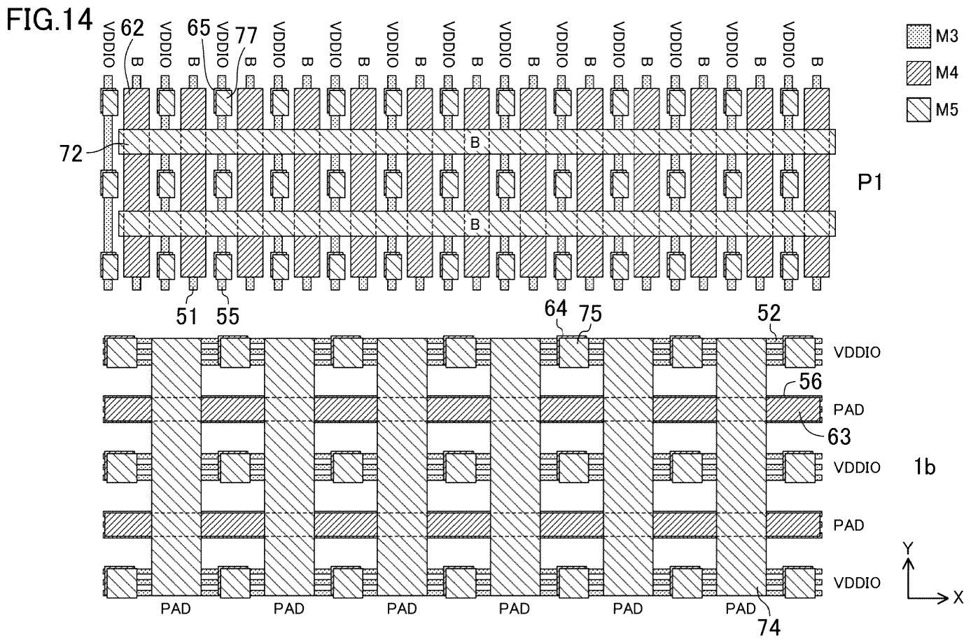

FIGS. 12 and 13 show layouts of an IO cell according to Alteration 1, and correspond to FIGS. 6 and 7, respectively, in the embodiment described above. That is, FIGS. 12 and 13 show planar structures of part A1 in FIG. 3, in which FIG. 12 shows the structure of the M3 to M5 interconnect layers and FIG. 13 shows the structure of the M5 to M6 interconnect layers. The structures below the M3 interconnect layer in this alteration are similar to those in FIGS. 4 and 5.

This alteration is different from the above embodiment in the structure of the M5 interconnects in the region of the ESD protection diode 1b. That is, while the M5 interconnects 74 extending in the Y direction are placed in the above embodiment, M5 interconnects 76 are placed at positions overlapping the M4 interconnects 63 extending in the X direction in planar view in a dotted manner. The M5 interconnects 76 are connected to the M4 interconnects 63 through contacts (not shown).

In this alteration, the M5 interconnects 76 connected to the external output terminal PAD are located between the M3 interconnects 52 connected to VDDIO, and therefore, as for the M3 interconnect layer, also, overlap only the M3 interconnects 56 connected to the external output terminal PAD in planar view. Therefore, no parasitic capacitance at the M5 interconnects 76 occurs between M3-M5 interconnect layers, in addition to the M4-M5 interconnect layers and the M5-M6 interconnect layers. Since this further reduces the parasitic capacitance related to the external output terminal PAD, further speedup can be achieved.

### (Alteration 2)

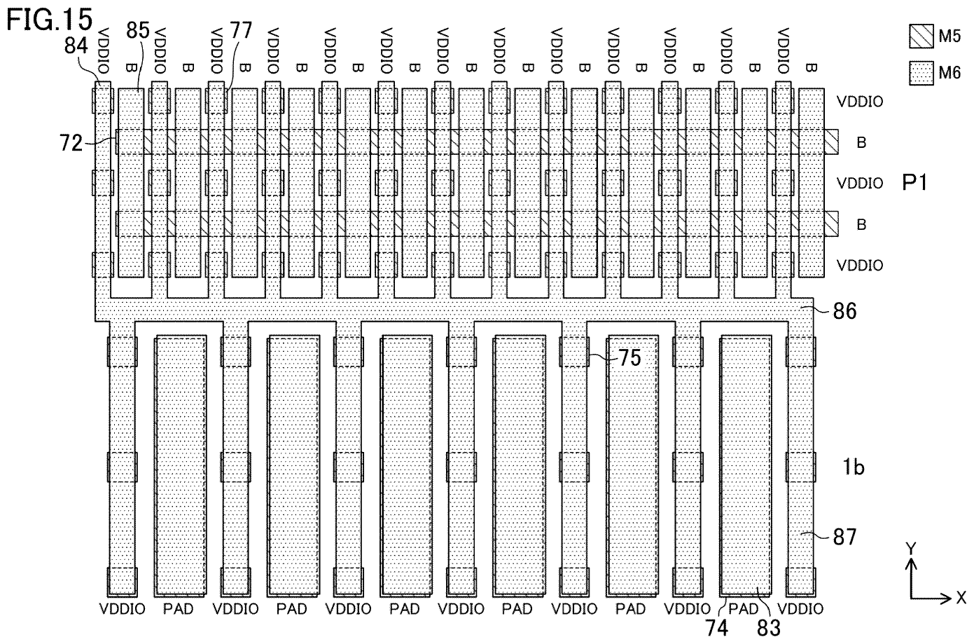

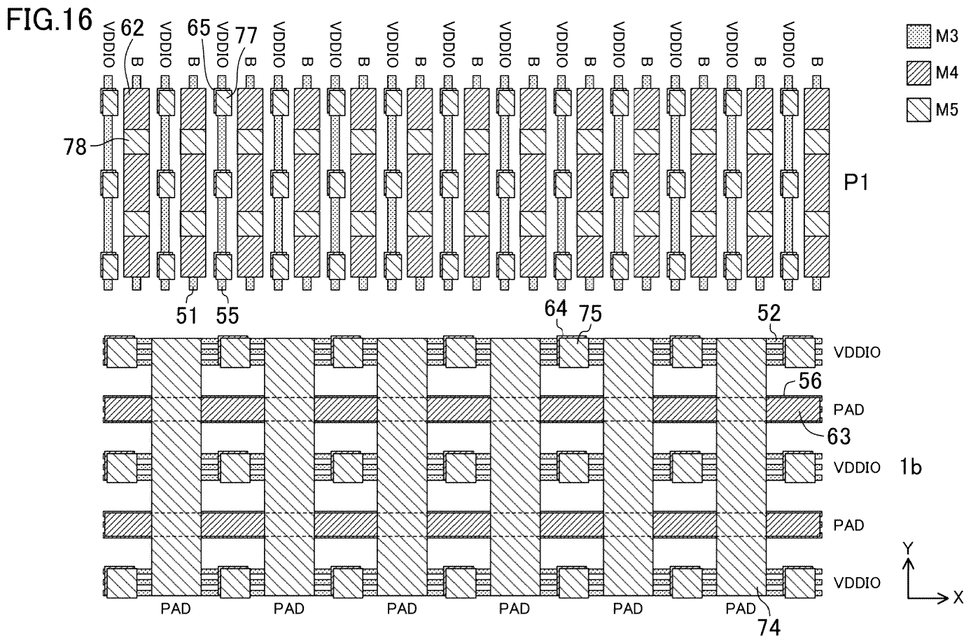

FIGS. 14 and 15 show layouts of an IO cell according to Alteration 2, and correspond to FIGS. 6 and 7, respectively, in the embodiment described above. That is, FIGS. 14 and 15 show planar structures of part A1 in FIG. 3, in which FIG. 14 shows the structure of the M3 to M5 interconnect layers and FIG. 15 shows the structure of the M5 to M6 interconnect layers. The structures below the M3 interconnect layer in this alteration are similar to those in FIGS. 4 and 5.

This alteration is different from the above embodiment in the structure of the M4 to M6 interconnects in the region of the output transistor P1. That is, in the above embodiment, the M4 interconnects 61 extending in the Y direction and the M5 interconnects 71 extending in the X direction are placed as the M4 interconnects and the M5 interconnects connected to VDDIO. In this alteration, however, M4 interconnects 65 and M5 interconnects 77 are placed in a dotted manner at positions overlapping the M3 interconnects 55 that extend in the Y direction and are connected to VDDIO in planar view. The M4 interconnects 65 are connected to the underlying M3 interconnects 55 through contacts (not shown), and the M5 interconnects 77 are connected to the underlying M4 interconnects 65 through contacts (not shown).

Moreover, in this alteration, the configuration of the M6 interconnects are also changed to conform to the changes of the M4 and M5 interconnects. That is, in the region of the output transistor P1, M6 interconnects 84 extending in the Y direction and M6 interconnects 85 extending in the Y direction are placed. The M6 interconnects 84 overlap the underlying

M5 interconnects 77 in planar view and are connected to the M5 interconnects 77 through contacts (not shown). The M6 interconnects 85 are connected to the M5 interconnects 72, which are connected to the node B, through contacts (not shown). Also, an M6 interconnect 86 extending in the X direction is placed to connect the M6 interconnects 84 and M6 interconnects 87 connected to VDDIO in the region of the ESD protection diode 1b.

In this alteration, the M4 interconnects 62 connected to the node B overlap only the M3 interconnects 51 connected to the node B in planar view as for the M3 interconnect layer. Also, the M4 interconnects 62 are located between the M5 interconnects 77 arranged in the X direction and separated from each other in planar view, and, as for the M5 interconnect layer, overlap only the M5 interconnects 72 connected to the node B in planar view. Also, the M5 interconnects 72 connected to the node B extend in the X direction, are located between the M4 interconnects 65 arranged in the Y direction and separated from each other in planar view, and, as for the M4 interconnect layer, overlap only the M4 interconnects 62 connected to the node B in planar view. Therefore, since the parasitic capacitance related to the node B is further reduced, further speedup can be achieved.

Although both the M4 interconnects and the M5 interconnects connected to VDDIO are placed in a dotted manner in this alteration, the configuration is not limited to this. That is, either the M4 interconnects or the M5 interconnects connected to VDDIO may be placed in a dotted manner. In this case, also, the effect of reducing the parasitic resistance related to the node B can be obtained.

### (Alteration 3)

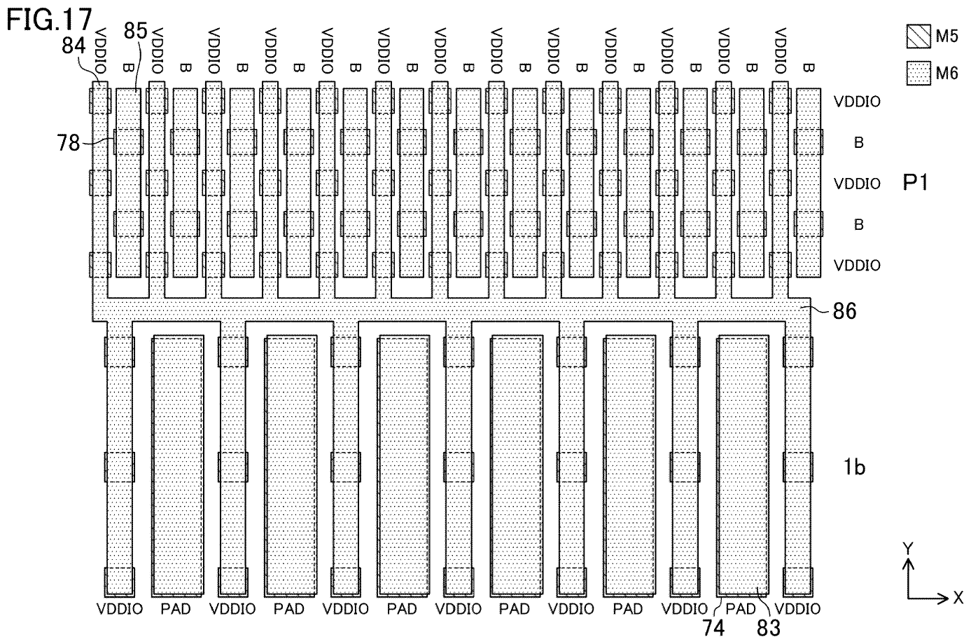

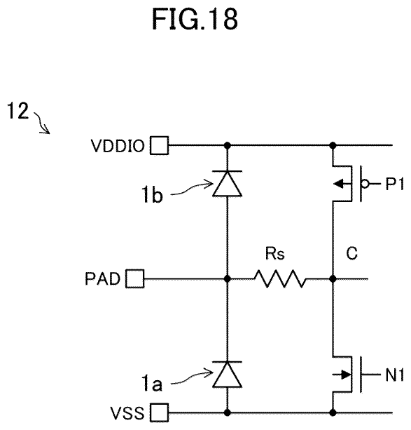

FIGS. 16 and 17 show layouts of an IO cell according to Alteration 3, and correspond to FIGS. 6 and 7, respectively, in the embodiment described above. That is, FIGS. 16 and 17 show planar structures of part A1 in FIG. 3, in which FIG. 16 shows the structure of the M3 to M5 interconnect layers and FIG. 17 shows the structure of the M5 to M6 interconnect layers. The structures below the M3 interconnect layer in this alteration are similar to those in FIGS. 4 and 5.

In this alteration, the configuration of the M5 interconnects in the region of the output transistor P1 is further changed from that in Alteration 2 described above. That is, in Alteration 2, the M5 interconnects 72 extending in the X direction are placed as the M5 interconnects connected to the node B. In this alteration, however, M5 interconnects 78 are placed in a dotted manner at positions overlapping the M4 interconnects 62 that extend in the Y direction and are connected to the node B in planar view. The M5 interconnects 78 are connected to the underlying M4 interconnects 62 through contacts (not shown).

In this alteration, the M5 interconnects 78 connected to the node B overlap only the M4 interconnects 62 connected to the node B in planar view as for the M4 interconnect layer, and, as for the M6 interconnect layer, overlap only the M6 interconnects 85 connected to the node B in planar view. Moreover, the M5 interconnects 78 are located between the M3 interconnects 55 connected to VDDIO and separated from each other, and, as for the M3 interconnect layer, also, overlap only the M3 interconnects 51 connected to the node B in planar view. Therefore, since the parasitic capacitance related to the node B is further reduced, further speedup can be achieved.

Note that Alterations 1 to 3 described above may be combined. For example, Alteration 1 related to the region of the ESD protection diode 1b and Alteration 2 or 3 related to the output transistor P1 may be executed in combination.

### Second Embodiment

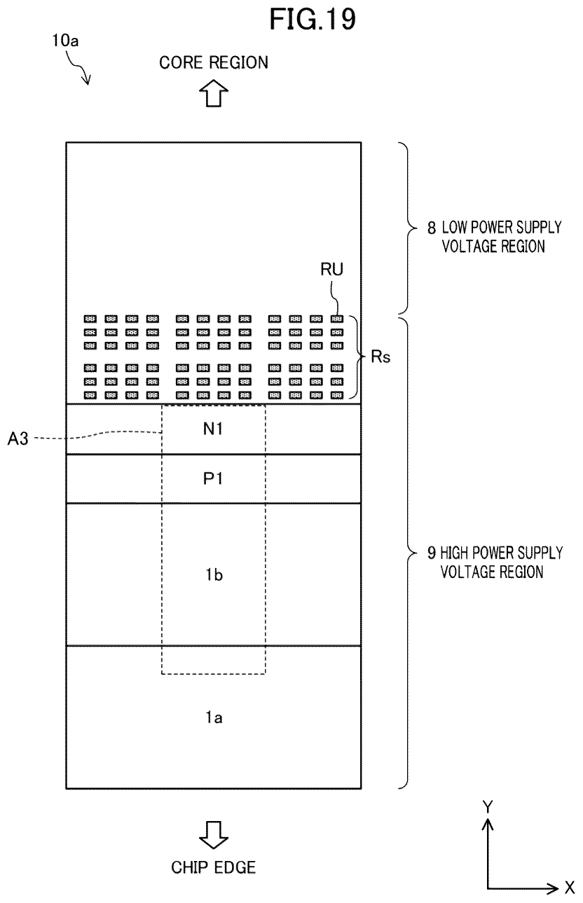

FIG. 18 is a circuit configuration diagram of an output circuit 12 according to this embodiment. The circuit configuration of FIG. 18 is similar to the circuit configuration of FIG. 2 in the first embodiment, except for the position of insertion of a protective resistance. That is, in the output circuit 12 of FIG. 18, a protective resistance Rs is provided in place of the protective resistances Rsn and Rsp in FIG. 2. In FIG. 18, the drains of the output transistors P1 and N1 are mutually connected, and the protective resistance Rs is provided between the external output terminal PAD and the drains of the output transistors P1 and N1. Note that the node between the drains of the output transistors P1 and N1 and the protective resistance Rs is herein called node C.

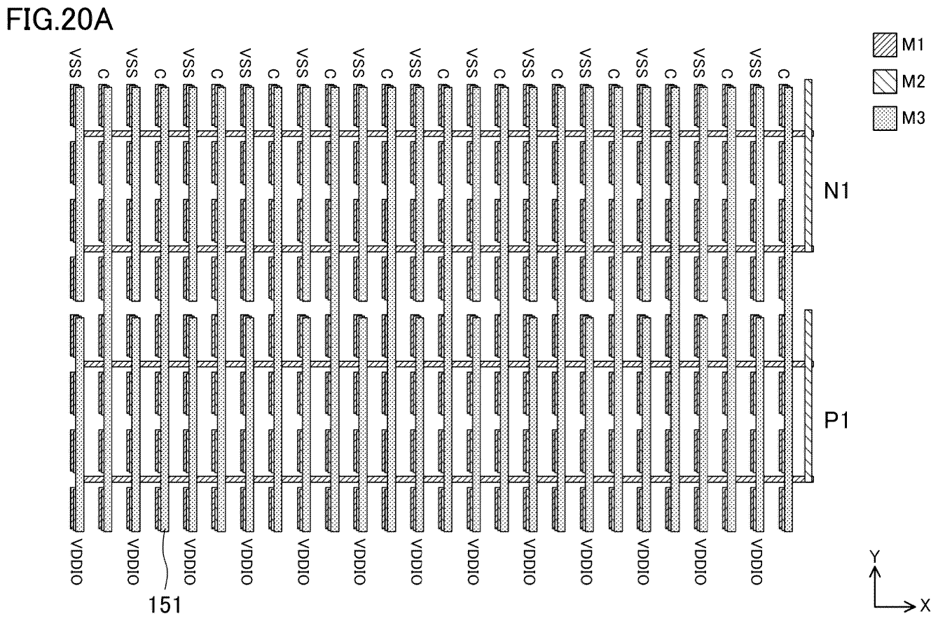

FIG. 19 shows an overview example of the layout of an IO cell. The layout of FIG. 19 corresponds to the IO cell 10a, one of the IO cells 10 arranged along the lower edge of the semiconductor integrated circuit device 1 in FIG. 1. In the IO cell layout of FIG. 19, the placement of the high power supply voltage region and the low power supply voltage region is different from that in the IO cell layout of FIG. 3. The IO cell 10a of FIG. 19 has a low power supply voltage region 8 and a high power supply voltage region 9 separated from each other in the Y direction. The low power supply voltage region 8 is located closer to the core region 2 and the high power supply voltage region 9 is located closer to the chip edge.

The IO cell 10a shown in FIG. 19 constitutes the output circuit 12 of FIG. 18. In the high power supply voltage region 9, the ESD protection diode 1a, the ESD protection diode 1b, the output transistor P1, and the output transistor N1 are placed in this order from the chip edge. In the high power supply voltage region 9, resistor elements RU are arranged in an array in the X-Y directions above a portion other than the portions where the ESD protection diode 1a, the ESD protection diode 1b, the output transistor P1, and the output transistor N1 are placed. The resistor elements RU are mutually connected to constitute the protective resistance Rs.

The connecting style of the resistor elements RU may be serial connection, parallel connection, or a combination of serial connection and parallel connection. Also, some of the resistor elements RU constituting the protective resistance Rs may lie above the low power supply voltage region 8.

The order of the placement of the ESD protection diode 1a, the ESD protection diode 1b, the output transistor P1, and the output transistor N1 is not limited to that shown in FIG. 19. For example, the placement positions of the output transistor P1 and the output transistor N1 may be changed with each other, and the placement positions of the ESD protection diode la and the ESD protection diode 1b may be changed with each other.

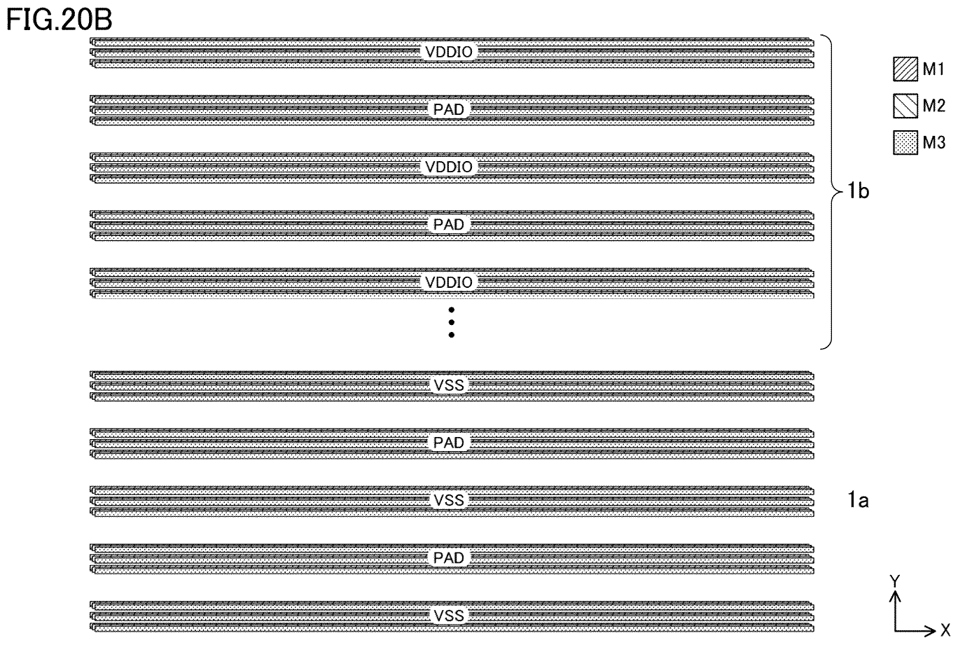

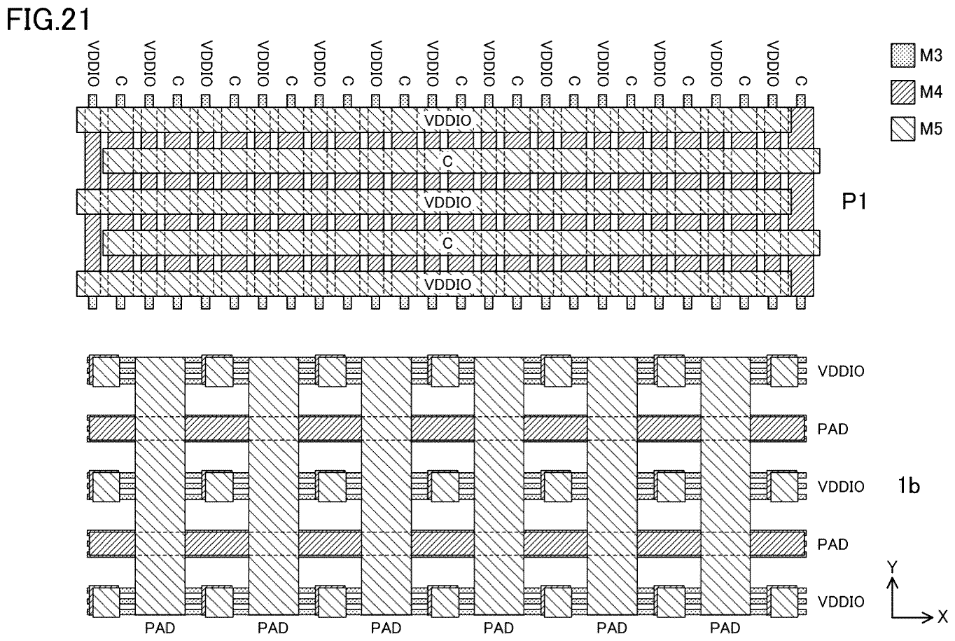

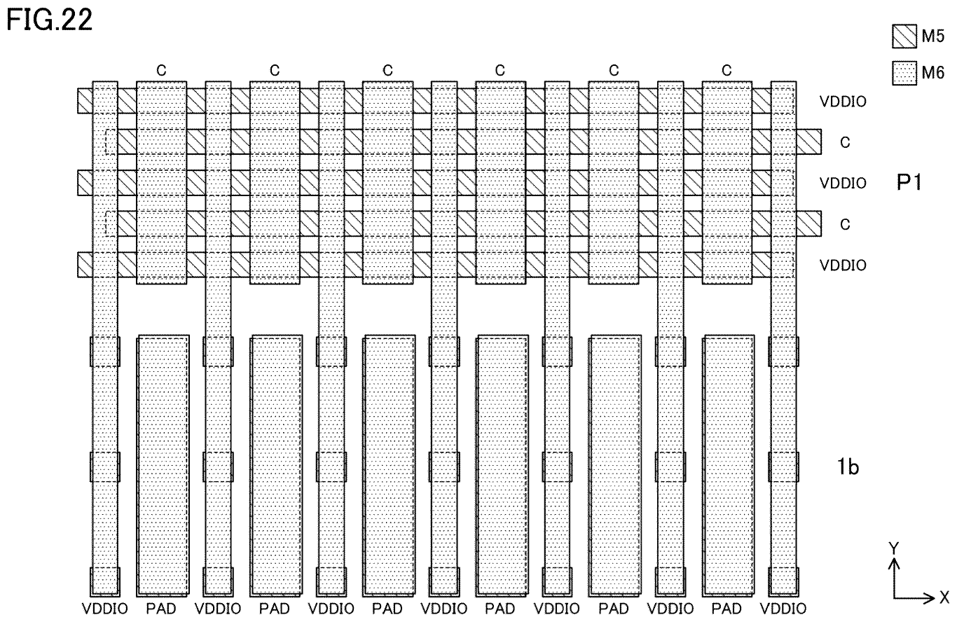

FIGS. 20A, 20B, 21, and 22 are plan views showing details of the layout of the IO cell, showing planar structures of part A3 in FIG. 19, i.e., the region in which the output transistors N1 and P1 and the ESD protection diodes 1a and 1b are placed. FIGS. 20A and 20B show the structure of M1 to M3 interconnect layers, FIG. 21 shows the structure of M3 to M5 interconnect layers, and FIG. 22 shows the structure of M5 to M6 interconnect layers. Note that FIGS. 21 and 22 show only the region of the output transistor P1 and the ESD protection diode 1b.

In this embodiment, the configuration of the region of the output transistors N1 and P1 and the ESD protection diodes 1b and 1a is basically similar to that in the first embodiment, and therefore detailed description thereof is omitted here in some cases. In this embodiment, however, the interconnects corresponding to the node B in the first embodiment are to correspond to the node C in the region of the output transistors N1 and P1.

Although illustration is omitted, the structure of layers below the M1 interconnect layer is similar to that in FIG. 4 for the region of the output transistor P1 and the ESD protection diode 1b and to that in FIG. 8 for the region of the output transistor N1 and the ESD protection diode 1a.

The structure of the M1 to M3 interconnect layers shown in FIGS. 20A and 20B is roughly similar to that in FIG. 5 for the region of the output transistor P1 and the ESD protection diode 1b and to that in FIG. 9 for the region of the output transistor N1 and the ESD protection diode 1a. However, M3 interconnects 151 extending in the Y direction, which correspond to the node C, are placed continuously from the region of the output transistor N1 to the region of the output transistor P1.

The structure of the M3 to M5 interconnect layers shown in FIG. 21 is similar to that in FIG. 6. Also, the structure of the M5 to M6 interconnect layers shown in FIG. 22 is similar to that in FIG. 7.

In this embodiment, effects similar to those in the first embodiment are obtained. That is, since the parasitic capacitance at the node C between the output transistors P1 and N1 is reduced, speedup of the circuit can be achieved. Also, since the parasitic resistances at the anode portions 28 of the ESD protection diode 1b and the cathode portions 28A of the ESD protection diode 1a, both connected to the external output terminal PAD, are reduced, speedup of the circuit can be achieved.

The alterations of the first embodiment are also applicable to this embodiment.

### (Alterations of Second Embodiment)

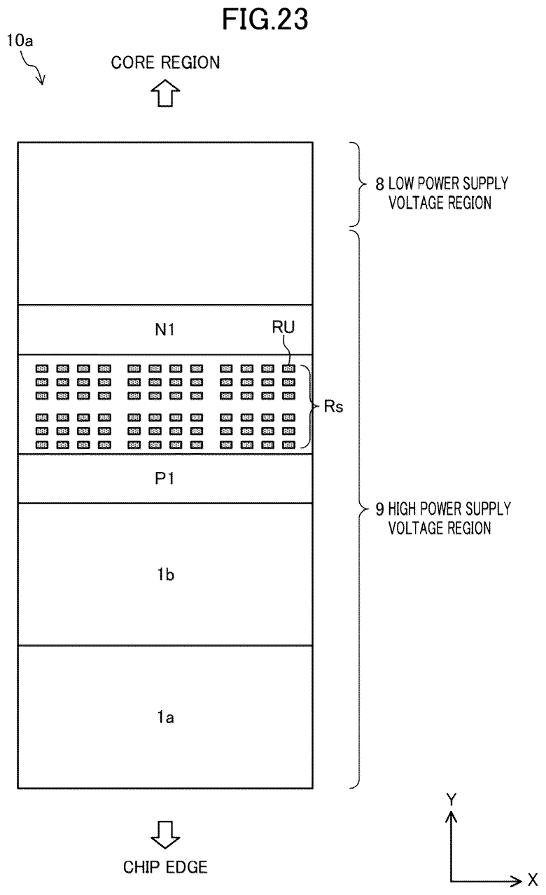

FIG. 23 shows an overview of an IO cell layout according to an alteration of the second embodiment. In the layout of FIG. 23, in comparison with the layout of FIG. 19, the placement position of the output transistor N1 is shifted upward as viewed in the figure. The protective resistance Rs is placed in a region between the output transistor N1 and the output transistor P1.

According to this alteration, the following effect is obtained in addition to the effects in the second embodiment. Since the output transistor N1 and the output transistor P1 are placed on both sides of the protective resistance Rs, the length of the interconnects between the protective resistance Rs and the output transistor N1 and the length of the interconnects between the protective resistance Rs and the output transistor P1 can be made roughly equal to each other. With this, unbalancing in interconnect parasitic components can be improved.

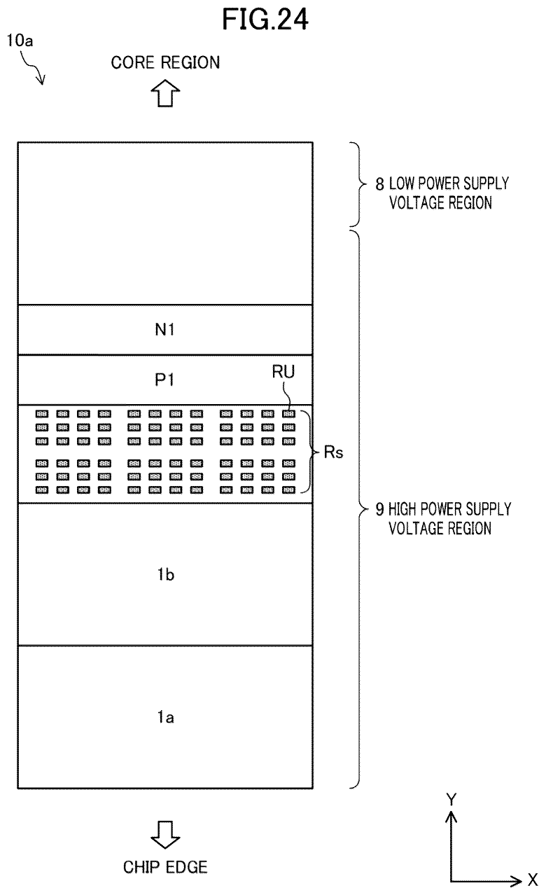

FIG. 24 shows an overview of an IO cell layout according to another alteration of the second embodiment. In the layout of FIG. 24, in comparison with the layout of FIG. 23, the placement position of the output transistor P1 is shifted upward as viewed in the figure. The protective resistance Rs is placed in a region below the output transistor P1 in the figure.

Note that while the ESD protection diodes 1a and 1b and the output transistors N1 and P1 are constituted by fins in the above embodiments, the configuration is not limited to this.

While the p-type transistors and the n-type transistors are all single-stage transistors in the output circuits in the above embodiments, the configuration is not limited to this. For example, they may be plural-stage transistors, such as two-or three-stage transistors, connected in series. Also, in the above embodiments, the output circuit can be an input/output circuit including an input circuit.

According to the present disclosure, in an output circuit included in an IO cell, since the parasitic capacitance at a signal terminal is reduced, speedup of the circuit can be achieved. The present disclosure is therefore useful for improving the performance of system LSI, for example.

1. A semiconductor integrated circuit device comprising a plurality of IO cells,
wherein
at least one of the plurality of IO cells includes an output circuit,
the output circuit includes
an external output terminal,
a protective resistance connected to the external output terminal at one end, and
an output transistor connected between the other end of the protective resistance and a first power supply,
the output transistor includes
a first transistor row including a plurality of transistors arranged in a first direction, and
a second transistor row including a plurality of transistors arranged in the first direction, the second transistor row being adjacent to the first transistor row in a second direction perpendicular to the first direction,
each of the transistors of the first and second transistor rows has a gate extending in the second direction, a source connected to the first power supply, and a drain connected to the other end of the protective resistance,
the output circuit includes
a first interconnect extending in the first direction in a first interconnect layer between the first transistor row and the second transistor row, and connected to the gates of the transistors of the first and second transistor rows,
a second interconnect extending in the second direction in a second interconnect layer located one layer above the first interconnect layer, and connected to the drains of the transistors of the first transistor row, and
a third interconnect extending in the second direction in the second interconnect layer, and connected to the drains of the transistors of the second transistor row, and
the first interconnect is located between the second interconnect and the third interconnect separated from each other in planar view.

2. The semiconductor integrated circuit device of claim 1, wherein
the second and third interconnects are placed at the same position in the first direction.

3. A semiconductor integrated circuit device comprising a plurality of IO cells,
wherein
at least one of the plurality of IO cells includes an output circuit,
the output circuit includes
an external output terminal,
an electrostatic discharge (ESD) protection diode having a first node connected to the external output terminal and a second node connected to a first power supply,
a first interconnect extending in a first direction in a first interconnect layer, and connected to the first node of the ESD protection diode,
second and third interconnects extending in the first direction in the first interconnect layer, connected to the second node of the ESD protection diode, and placed on both sides of the first interconnect in a second direction perpendicular to the first direction,
a fourth interconnect extending in the first direction in a second interconnect layer one layer above the first interconnect layer, overlapping the first interconnect in planar view, and connected to the first interconnect,
a fifth interconnect in the second interconnect layer, overlapping the second interconnect in planar view, and connected to the second interconnect,
a sixth interconnect in the second interconnect layer, overlapping the third interconnect in planar view, and connected to the third interconnect,
a seventh interconnect placed in a third interconnect layer, and connected to the fourth interconnect,
an eighth interconnect placed in the third interconnect layer, overlapping the fifth interconnect in planar view, and connected to the fifth interconnect, and
a ninth interconnect placed in the third interconnect layer, overlapping the sixth interconnect in planar view, and connected to the sixth interconnect, and
the fourth interconnect is located between the eighth interconnect and the ninth interconnect separated from each other in planar view.

4. The semiconductor integrated circuit device of claim 3, wherein
the seventh interconnect extends in the second direction,
the output circuit includes
a tenth interconnect in the second interconnect layer, overlapping the second interconnect in planar view, connected to the second interconnect, and being adjacent to the fifth interconnect in the first direction, and
the seventh interconnect is located between the fifth interconnect and the tenth interconnect separated from each other in planar view.

5. The semiconductor integrated circuit device of claim 3, wherein
the seventh interconnect is located between the second interconnect and the third interconnect separated from each other in planar view.

6. A semiconductor integrated circuit device comprising a plurality of IO cells,
wherein
at least one of the plurality of IO cells includes an output circuit,
the output circuit includes
an external output terminal,
a protective resistance connected to the external output terminal at one end, and
an output transistor connected between the other end of the protective resistance and a first power supply,
the output transistor includes a plurality of transistors arranged in a first direction, each of the plurality of transistors has a gate extending in a second direction perpendicular to the first direction, a source connected to the first power supply, and a drain connected to the other end of the protective resistance,
the output circuit includes
a first interconnect extending in the second direction in a first interconnect layer, and connected to the drains of some of the plurality of transistors,
second and third interconnects extending in the second direction in the first interconnect layer, placed on both sides of the first interconnect in the first direction, and connected to the sources of some of the plurality of transistors,
a fourth interconnect extending in the second direction in a second interconnect layer one layer above the first interconnect layer, overlapping the first interconnect in planar view, and connected to the first interconnect,
a fifth interconnect in the second interconnect layer, overlapping the second interconnect in planar view, and connected to the second interconnect,
a sixth interconnect in the second interconnect layer, overlapping the third interconnect in planar view, and connected to the third interconnect,
a seventh interconnect placed in a third interconnect layer, and connected to the fourth interconnect,
an eighth interconnect placed in the third interconnect layer, overlapping the fifth interconnect in planar view, and connected to the fifth interconnect, and
a ninth interconnect placed in the third interconnect layer, overlapping the sixth interconnect in planar view, and connected to the sixth interconnect, and
the fourth interconnect is located between the eighth interconnect and the ninth interconnect separated from each other in planar view.

7. The semiconductor integrated circuit device of claim 6, wherein
the seventh interconnect extends in the first direction,
the output circuit includes
a tenth interconnect in the second interconnect layer, being adjacent to the fifth interconnect in the second direction, overlapping the second interconnect in planar view, and connected to the second interconnect, and
the seventh interconnect is located between the fifth interconnect and the tenth interconnect separated from each other in planar view.

8. The semiconductor integrated circuit device of claim 6, wherein
the seventh interconnect is located between the second interconnect and the third interconnect separated from each other in planar view.
